(19) United States
(12) Patent Application Publication
(10) Pub. No.: US 2025/0015191 A1
(43) Pub. Date: Jan. 9, 2025

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Chien-Hao HUANG, Hsinchu (TW); Tzu-Hsiang HSU, Hsinchu (TW); Kuo-Chang CHIANG, Hsinchu (TW); Katherine H. CHIANG, Hsinchu (TW)

(73) Assignee: Taiwan Semiconductor Manufacturing Company, Ltd., Hsinchu (TW)

(21) Appl. No.: 18/218,927

(22) Filed: Jul. 6, 2023

(51) Int. Cl. H01L 29/786; H01L 29/66

(52) U.S. Cl. CPC H01L 29/7869; H01L 29/66969

(57) ABSTRACT

A semiconductor device includes a FEOL structure and a BEOL structure. The BEOL structure is formed over the FEOL structure and includes a barrier dielectric layer, a transistor and a first barrier. The barrier dielectric layer has an upper surface and a lower surface. The transistor is partially formed in the barrier dielectric layer and includes an electrode element, and the electrode element has a first lateral surface, wherein the first lateral surface extends from the upper surface toward the lower surface. The first barrier covers the entirety of the first lateral surface of the electrode element.

### BACKGROUND

A semiconductor device normally includes at least one transistor, the transistors provide the function of amplifying and switching electrical signals. The transistor can work when a predetermined signal arrives, at this time it acts as a switch. In general, all transistors of the semiconductor device are formed within a FEOL structure of the semiconductor device in a FEOL process.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1a illustrates a schematic diagram of a cross-sectional view of a semiconductor device in a first direction;

FIG. 1B illustrates a schematic diagram of a cross-sectional view of a semiconductor device in a second direction;

FIG. 2a illustrates a schematic diagram of a cross-sectional view of a semiconductor device in the first direction;

FIG. 2b illustrates a schematic diagram of a cross-sectional view of a semiconductor device in the second direction;

FIGS. 3A_a to 3E_b illustrate schematic diagrams of manufacturing processes of the semiconductor device of FIGS. 1a and 1b; and

FIGS. 4A_a to 4E_b illustrate schematic diagrams of manufacturing processes of the semiconductor device of FIGS. 2a and 2b.

### DETAILED DESCRIPTiON

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

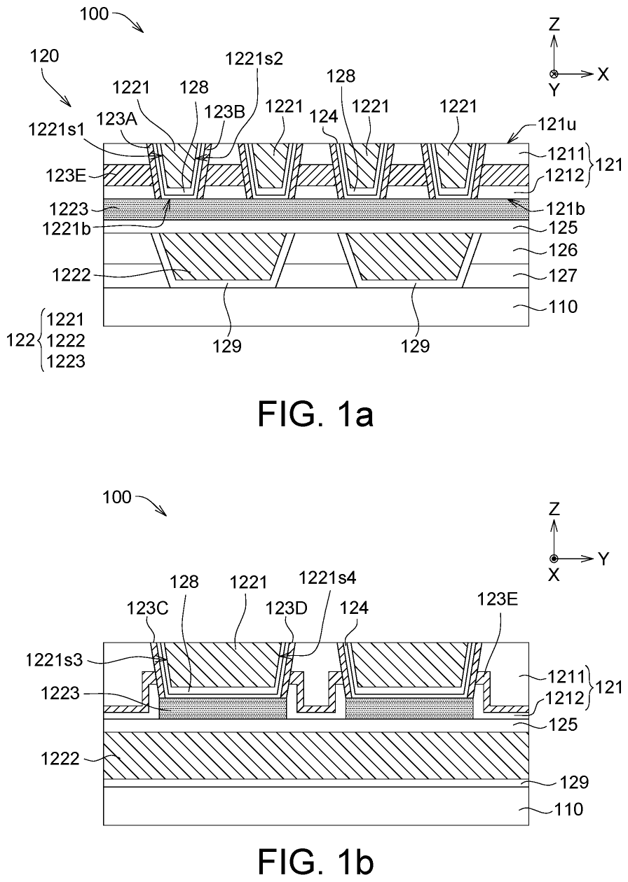

Referring to FIGS. 1a and 1b, FIG. 1a illustrates a schematic diagram of a cross-sectional view of a semiconductor device 100 in a first direction, and FIG. 1b illustrates a schematic diagram of a cross-sectional view of a semiconductor device 100 in a second direction. The semiconductor device 100 may include a plurality of transistors (for example, Thin-Film Transistor) formed on a FEOL (Front End Of Line) structure and a BFOL (Back End Of Line) structure. The FEOL structure may include at least one gate-all-around (GAA) component, at least one nanosheet component and/or at least one forksheet component.

As illustrated in FIGS. 1a and 1b, the semiconductor device 100 includes a FEOL structure 110 and a BEOL structure 120. The BEOL structure 120 is formed over the FEOL structure 110. The BEOL structure 120 includes a barrier dielectric layer 121, at least one transistor 122, a first barrier 123A, a second barrier 123B, a third barrier 123C, a fourth barrier 123D, a fifth barrier 123E, an electrode spacer 124, a gate dielectric layer 125, another dielectric layer 126, an etching stop layer (ESL) 127, at least one electrode connection layer 128 and at least one gate connection layer 129. The barrier dielectric layer 121 has an upper surface 121u and a lower surface 121b. The transistor 122 is partially formed in the barrier dielectric layer 121 and includes at least one electrode element 1221, wherein the electrode element 1221 has a first lateral surface 1221s1, wherein the first lateral surface 1221s1 extends from the upper surface 121u toward the lower surface 121b. The first barrier 123A covers an entirety of the first lateral surface 1221s1 of the electrode element 1221. In addition, an upper surface of the first barrier 123A is substantially coplanar with the upper surface 121u of the barrier dielectric layer 121 and an upper surface of the electrode element 1221 by, for example, a CMP, and a lower surface of the first barrier 123A is substantially coplanar with the lower surface 121b of the barrier dielectric layer 121 and a lower surface of the electrode element 1221.

In an embodiment, the BEOL structure 120 includes a plurality of layers (for example, metal M0 to metal Mx, wherein x is a positive integer greater than 1), and at least one transistor 122 may be formed within any one of the layers. In addition, the FEOL structure 110 may further include at least one signal line and/or at least one power line electrically to at least one component of the BEOL structure 120. The BEOL structure 120 and the FEOL structure 110 arte different in component size, line width/line space (L/S), process temperature, process parameter, material, etc.

As illustrated in FIGS. 1a and 1b, the barrier dielectric layer 121 may be formed of a material comprising, for example, oxide material. In an embodiment, the barrier dielectric layer 121 is, for example, an interlayer dielectric (ILD) layer. Each electrode element 1221 is a source of the transistor 122 or a drain of the transistor 122. For example, a pair of the electrode elements 1221 is formed over the gate 1222 and disposed at opposite sides of the gate 1222, one of the pair of the electrode elements 1221 is a source and the other of the pair of the electrode elements 1221 is a drain. The electrode element 1221 may be formed of a material including, for example, copper, tungsten, TiN, etc.

As illustrated in FIG. 1a, the electrode element 1221 further has a second lateral surface 1221s2 opposite to the first lateral surface 1221s1, and the second lateral surface 1221s2 extends from the upper surface 121u toward the lower surface 121b. The second barrier 123B covers the entirety of the second lateral surface 1221s2 of the electrode element 1221. In addition, an upper surface of the second barrier 123B is substantially coplanar with the upper surface 121u of the barrier dielectric layer 121 and an upper surface of the electrode element 1221 by, for example, a CMP, and a lower surface of the second barrier 123B is substantially coplanar with the lower surface 121b of the barrier dielectric layer 121 and a lower surface of the electrode element 1221.

As illustrated in FIG. 1b, the electrode element 1221 further has a third lateral surface 1221s3 and a fourth surface 1221s4 opposite to the third lateral surface 1221s3, the third lateral surface 1221s3 extends from the upper surface 121u toward the lower surface 121b, and the fourth lateral surface 1221s4 extends from the upper surface 121u toward the lower surface 121b. The third barrier 123C covers the entirety of the third lateral surface 1221s3 of the electrode element 1221, and the fourth barrier 123D covers the entirety of the fourth lateral surface 1221s4 of the electrode element 1221.

As illustrated in FIGS. 1a and 1b, in the present embodiment, the first barrier 123A, the second barrier 123B, the third barrier 123C and the fourth barrier 123D surround at least one portion of the entirety sidewall (or outer boundary) of the electrode element 1221. In an embodiment, at least one of the barrier layers 123A, 123B, 123C, 123D and 123E isolates the barrier dielectric layer 121 (or other dielectric layer) from the electrode element 1221. In an embodiment, the barrier layers 123A, 123B, 123C, 123D and 123E may be collectively called a barrier layer. In an embodiment, the first barrier 123A, the second barrier 123B, the third barrier 123C and the fourth barrier 123D may be physically connected as a closed-ring or an open-ring (viewed from a top of the semiconductor device 100) surrounding the electrode element 1221.

As illustrated in FIGS. 1a and 1b, the transistor 122 further includes a gate 1222 and an active layer 1223. Each transistor 122 at least includes the electrode elements 1221, the gate 1222 and the active layer 1223. The active layer 1223 is formed between the gate 1222 and the electrode element 1221 and extends in a direction, for example, the axis X. The gate 1222 is formed in the dielectric layer 126 and the etching stop layer 127. In addition, the gate 1222 may be formed of a material the same as that of the electrode element 1221. For example, the gate 1222 may be formed of a material including, for example, copper, tungsten, TiN, etc. The active layer 1223 may be formed of a material including, for example, IGZO, InO, ITO, etc.

As illustrated in FIGS. 1a and 1b, the fifth barrier 123E extends in the direction (for example, the axis X), wherein the fifth barrier 123E is connected to the first barrier 123A. In the present embodiment, the fifth barrier 123E divides the barrier dielectric layer 121. For example, the barrier dielectric layer 121 includes an upper portion 1211 and a lower portion 1212, wherein the fifth barrier 123E separates the upper portion 1211 from the lower portion 1212.

The barriers 123A, 123B, 123C, 123D and 123E may block the impurity (for example, oxygen ion and/or hydrogen ion) in the dielectric layer from electrode element 1221 and/or the active layer 1223, which prevents from the impurity invading the electrode element 1221 and/or the active layer 1223 of the transistor 122 (along the direction of the electric field when the transistor operates), and accordingly the sensitivity of the transistor may be maintained or even promoted and the reliability is improved. In addition, the barrier may be formed of a material including but not limited to AlOₓ, HfOₓ, SiNₓ, TiOₓ, SiCN, NiO, Fe₂O₃, Co₃O₄, MoO₂, Mn₃O₄, CuO, Sb₂O₃, SnO, Cr₂O₃, rare earth oxide, Ca—/Sr—/Bi-related Perovskite material (for example, copper, tungsten, TiN, etc.) or a combination thereof. In addition, each of the barriers 123A, 123B, 123C, 123D and 123E may have a thickness ranging 1 nanometer (nm) and 20 nm, even greater or less, wherein the thickness of the barrier 123E may be different or the same as that of the thickness of barrier 123A, 123B, 123C and/or 123D.

As illustrated in FIGS. 1a and 1b, the electrode spacer 124 is formed on the electrode connection layer 128 or the electrode element 1221. For example, the electrode spacer 124 is formed on the first lateral surface 1221s1, the second lateral surface 1221s2, the third lateral surface 1221s3 and the fourth lateral surface 1221s4 through the electrode connection layer 128. In the present embodiment, the electrode spacer 124 is formed between the electrode element 1221 and at least one barrier (for example, the barrier 123A, 123B, 123C and/or 123D).

As illustrated in FIGS. 1a and 1b, the gate dielectric layer 125 is formed between the active layer 1223 and the gate 1222. The dielectric layer 126 is formed between the gate dielectric layer 125 and the etching stop layer 127. The gate dielectric layer 125 may be formed of a material including but not limited to HfOₓ, AlOₓ, etc. The dielectric layer 126 may be formed of a material comprising, for example, oxide material. In an embodiment, the dielectric layer 126 is, for example, an ILD layer. The etching stop layer 127 may be formed of a material including but not limited to AlOₓ, AlN, SiON, etc. The electrode connection layer 128 is formed between the electrode element 1221 and the electrode spacer 124. In addition, the electrode connection layer 128 may be formed of a material including, for example, glue material, or barrier material. The gate connection layer 129 is formed within the dielectric layer 126 and the etching stop layer 127, and the gate connection layer 129 is formed between the gate 1222 and the dielectric layer 126. The gate connection layer 129 may be formed of a material the same as or similar to that of the electrode connection layer 128.

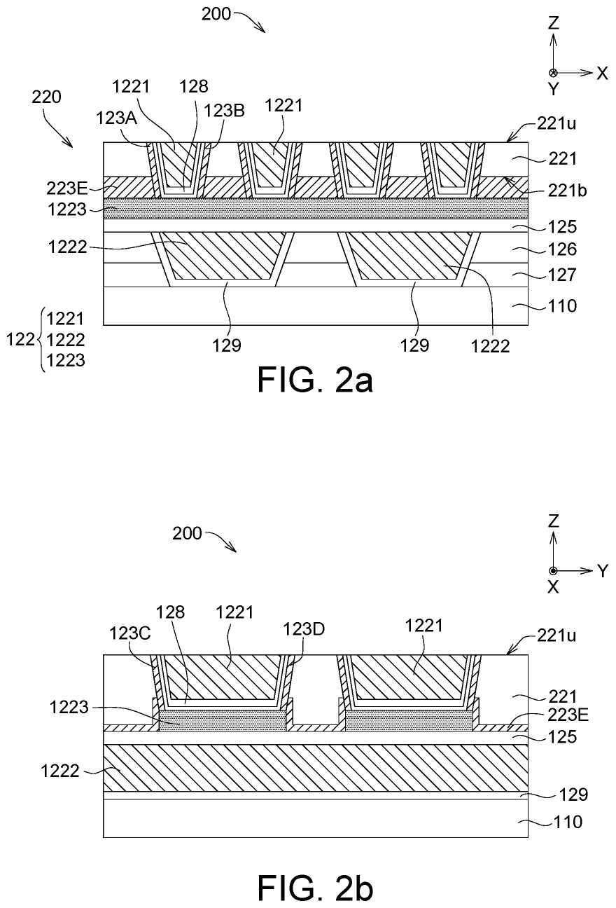

Referring to FIGS. 2a and 2b, FIG. 2a illustrates a schematic diagram of a cross-sectional view of a semiconductor device 200 in the first direction, and FIG. 2b illustrates a schematic diagram of a cross-sectional view of a semiconductor device 200 in the second direction. The semiconductor device 200 may include a plurality of transistors (for example, Thin-Film Transistor) formed on the FEOL structure and the BFOL structure.

As illustrated in FIGS. 2a and 2b, the semiconductor device 200 includes the FEOL structure 110 and a BEOL structure 220. The BEOL structure 220 is formed over the FEOL structure 110. The BEOL structure 220 includes a barrier dielectric layer 221, at least one transistor 122, the first barrier 123A, the second barrier 123B, the third barrier 123C, the fourth barrier 123D, a fifth barrier 223E, the electrode spacer 124, the gate dielectric layer 125, another dielectric layer 126, the etching stop layer 127, at least one electrode connection layer 128 and at least one gate connection layer 129. The barrier dielectric layer 221 has an upper surface 221u and a lower surface 221b. The transistor 122 is formed in the barrier dielectric layer 221 and includes the electrode element 1221, wherein the electrode element 1221 has the first lateral surface 1221s1, wherein the first lateral surface 1221s1 extends from the upper surface 221u toward the lower surface 221b. The first barrier 123A covers the entirety of the first lateral surface 1221s1 of the electrode element 1221.

The semiconductor device 200 includes the features the same as or similar to that of the semiconductor device 100, and at least one difference is that the fifth barrier 223E is in contact with the gate dielectric layer 125 (as shown in FIG. 2b), and the fifth barrier 223E is in contact with active layer 1223 (as shown in FIG. 2a).

The barrier dielectric layer 221 may be formed of a material the same as or similar to that o barrier dielectric layer 121.

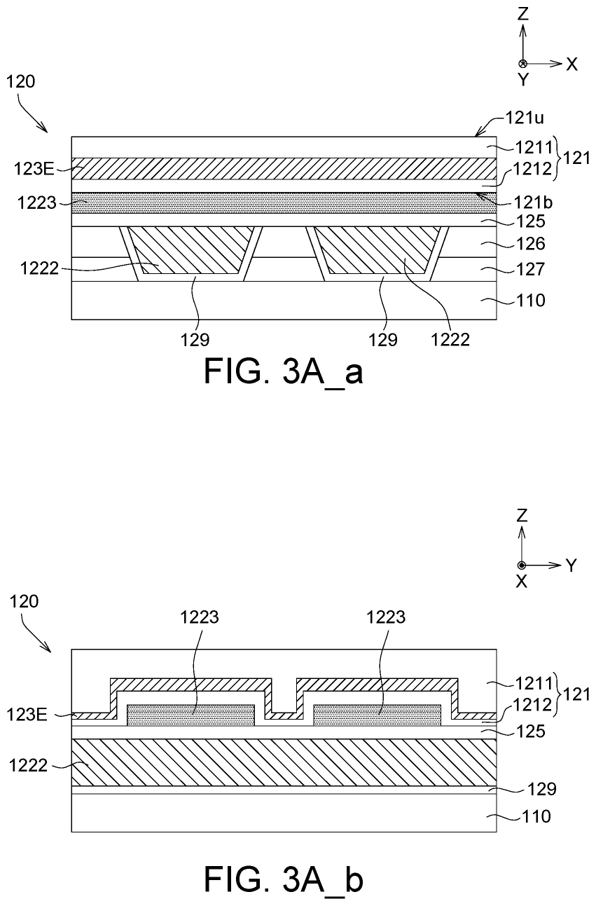

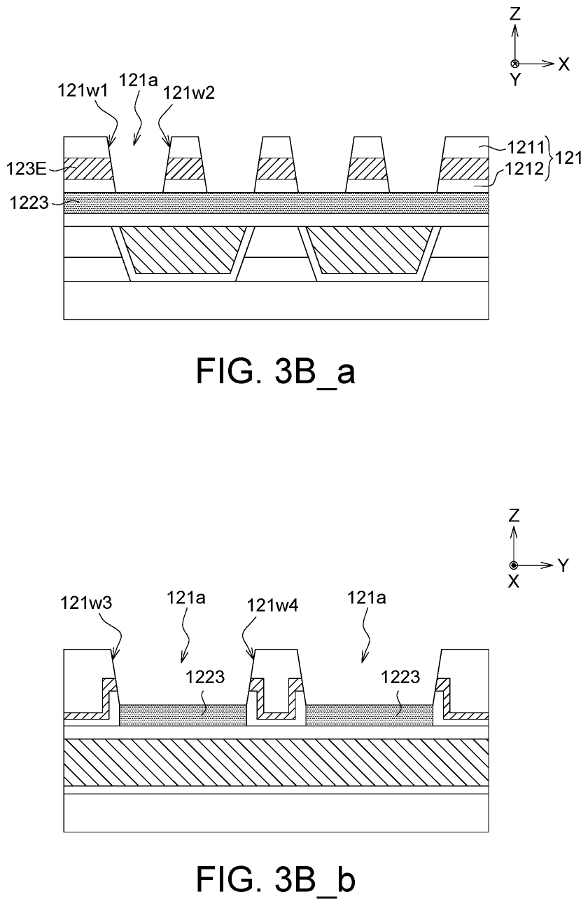

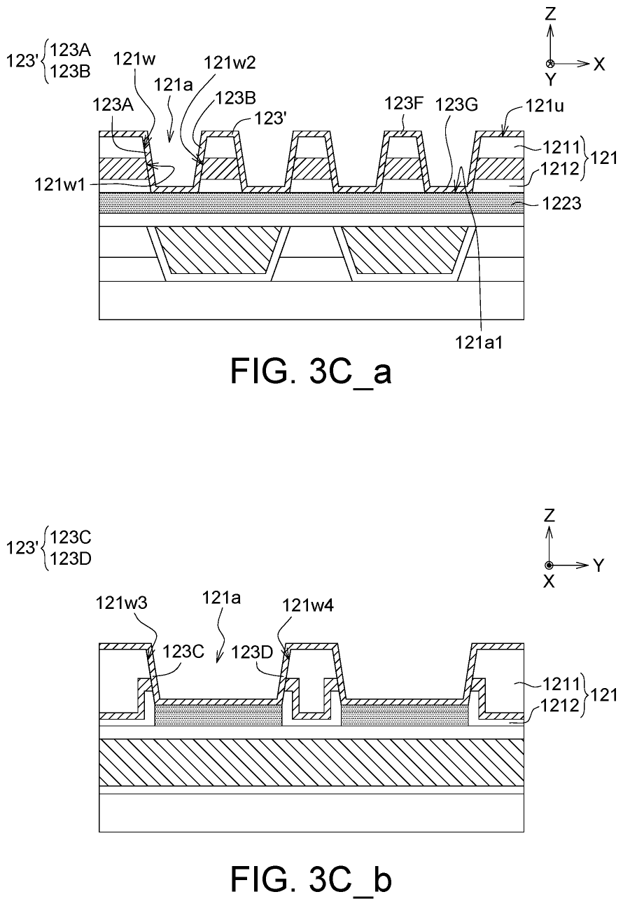

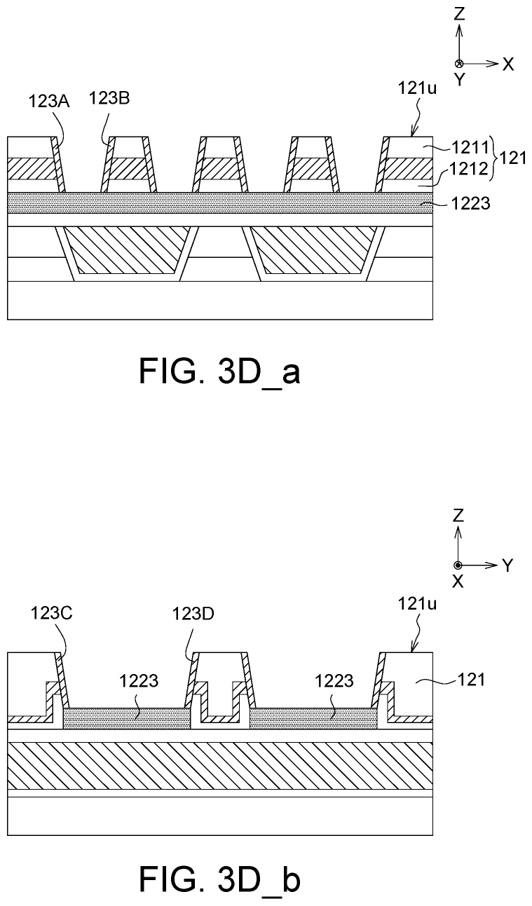

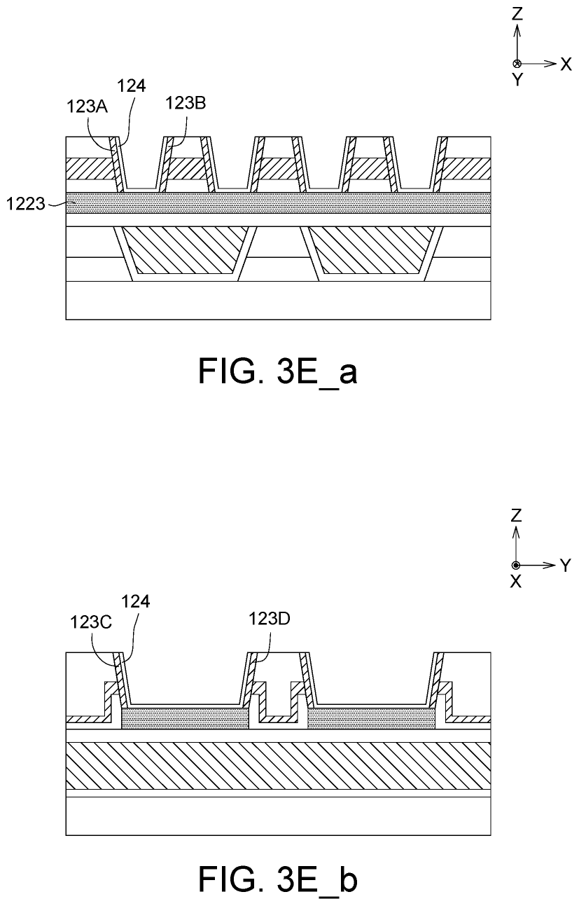

Referring to FIGS. 3A_a to 3E_b, FIGS. 3A_a to 3E_b illustrate schematic diagrams of manufacturing processes of the semiconductor device 100 of FIGS. 1a and 1b.

As shown in FIGS. 3A_a and 3A b, the barrier dielectric layer 121 within the BEOL structure 120 is formed, wherein the BEOL structure 120 is formed on the FEOL structure 110, and the barrier dielectric layer 121 has the upper surface 121u and the lower surface 121b. The BEOL structure 120 further includes the fifth barrier 123E, and the barrier dielectric layer 121 includes the upper portion 1211 and the lower portion 1212, wherein the fifth barrier 123E separates the upper portion 1211 from the lower portion 1212.

The barrier dielectric layer 121 is etched in hydrogen atmosphere and/or annealed in hydrogen atmosphere. Thus, the hydrogen may remain in the barrier dielectric layer 121. The hydrogen may be an impurity diffused into other elements.

In FIGS. 3A_a and 3A b, the BEOL structure 120 further includes the active layer 1223, at least one gate 1222, the gate dielectric layer 125, the dielectric layer 126, the etching stop layer 127 and the gate connection layer 129.

The gate 1222 is formed in the dielectric layer 126 and the etching stop layer 127. The active layer 1223 is formed between the gate 1222 (or the gate dielectric layer 125) and the barrier dielectric layer 121 (or the lower portion 1212), and extends in a direction, for example, the axis X. The active layer 1223 has an upper surface, wherein the upper surface is, for example, a flat surface by, for example, a CMP. The gate dielectric layer 125 is formed between the active layer 1223 and the gate 1222. The dielectric layer 126 is formed between the gate dielectric layer 125 and the etching stop layer 127. The gate connection layer 129 is formed within the dielectric layer 126 and the etching stop layer 127, and the gate connection layer 129 is formed between the gate 1222 and the dielectric layer 126.

The gate dielectric layer 125 may be formed of a material including but not limited to HfOₓ, AlOₓ, etc, the dielectric layer 126 is, for example, an ILD layer, and the etching stop layer 127 may be formed of a material including but not limited to AlOₓ, AlN, SiON, etc. the electrode connection layer 128 may be formed of a material including, for example, glue material, or barrier material. The gate connection layer 129 may be formed of a material the same as or similar to that of the electrode connection layer 128. The gate 1222 may be formed of a conductive material including, for example, copper, tungsten, TiN, etc. The active layer 1223 may be formed of a material including, for example, IGZO, InO, ITO, etc.

As shown in FIGS. 3B_a and 3B_b, the barrier dielectric layer 121 and the fifth barrier 123E are patterned. Furthermore, at least one through hole 121a passing through the barrier dielectric layer 121 and the fifth barrier 123E is formed by using photolithography including exposure, development and/or etching. After the through hole 121a being formed, the active layer 1223 is exposed from the through hole 121a. The through hole 121a has a first inner wall 121w1, a second inner wall 121w2 opposite to the first inner wall 121w1, a third inner wall 121w3 and a fourth inner wall 121w4 opposite to the third inner wall 121w3.

As shown in FIGS. 3C_a and 3C_b, a barrier layer 123′ over the first inner wall 121w1, the second inner wall 121w2, the third inner wall 121w3 and the fourth inner wall 121w4 of the through hole 121a and the upper surface 121u of the barrier dielectric layer 121 is formed by using, for example, deposition, such as a CVD (Chemical Vapor Deposition), a PVD (Physical vapor deposition), a ALD (Atomic layer deposition), etc. The barrier layer 123′ includes the first barrier 123A, the second barrier 123B, the third barrier 123C, the fourth barrier 123D, an upper portion 123F and a lower portion 123G, wherein the first barrier 123A covers the entirety of the first inner wall 121w1 of the through hole 121a, the second barrier 123B covers the entirety of the second inner wall 121w2 of the through hole 121a, the third barrier 123C covers the entirety of the third inner wall 121w3 of the through hole 121a, the fourth barrier 123D covers the entirety of the fourth inner wall 121w4 of the through hole 121a, the upper portion 123F covers the upper surface 121u of the barrier dielectric layer 121, and the lower portion 123G covers a bottom surface 121al of the through hole 121a which exposes the active layer 1223.

As shown in FIGS. 3D_a and 3D_b, a portion of the barrier layer 123′ is removed. Furthermore, the upper portion 123F and the lower portion 123G of FIGS. 3C_a and 3C_b are removed by using, for example, etching back, etc. After the upper portion 123F and the lower portion 123G are removed, the upper surface 121u and the active layer 1223 are exposed. In addition, the barrier layer 123′ may be formed of a material including but not limited to AlOₓ, HfOₓ, SiNₓ, TiON, SiCN, NiO, Fe₂O₃, Co₃O₄, MoO₂, Mn₃O₄, CuO, Sb₂O₃, SnO, Cr₂O₃, rare earth oxide, Ca—/Sr—/Bi-related Perovskite material (for example, copper, tungsten, TiN, etc.) or a combination thereof.

The barrier layer may block the impurity (for example, oxygen ion and/or hydrogen ion) in the dielectric layer from electrode element 1221 formed in subsequent process and/or the active layer 1223, which prevents from the impurity invading (along the direction of the electric field when the transistor operates) the electrode element 1221 and/or the active layer 1223 of the transistor 122, and accordingly the sensitivity of the transistor may be maintained or even promoted and the reliability is improved.

As shown in FIGS. 3E_a and 3E_b, the electrode spacer 124 over the first barrier 123A, the second barrier 123B, the third barrier 123C, the fourth barrier 123D and the active layer 1223 is formed by deposition, etc.

Then, at least one electrode connection layer 128 and at least one the electrode element 1221 filling the through hole 121a is formed by deposition, etc., and then electrode connection layer 128 and the electrode element 1221 may be planarized by using a CMP to form the semiconductor device 100 as shown in FIGS. 1a and 1b. The electrode connection layer 128 is formed between the electrode element 1221 and the electrode spacer 124.

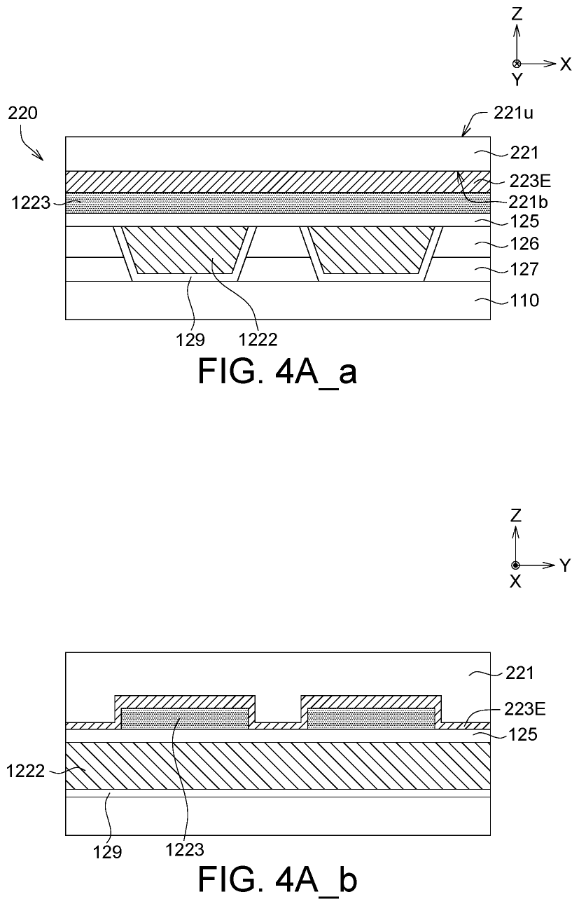

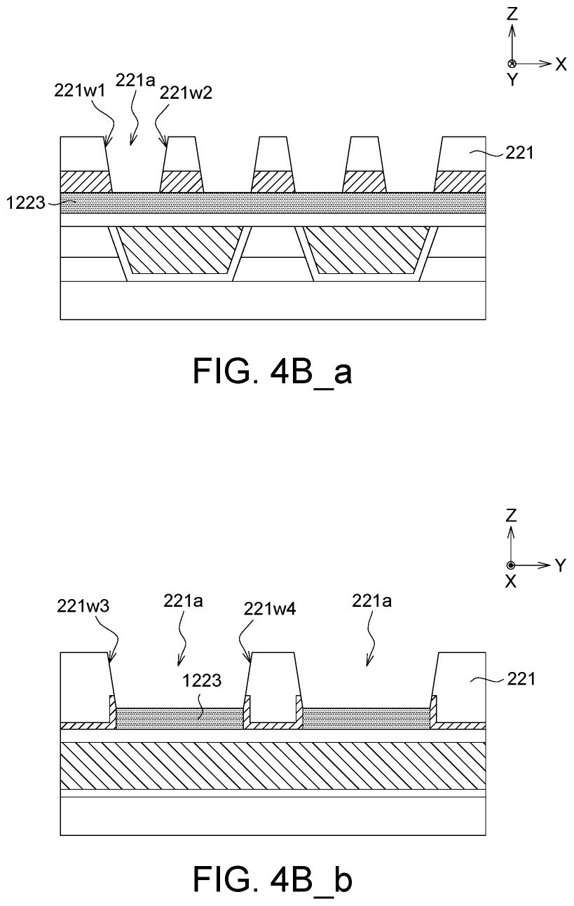

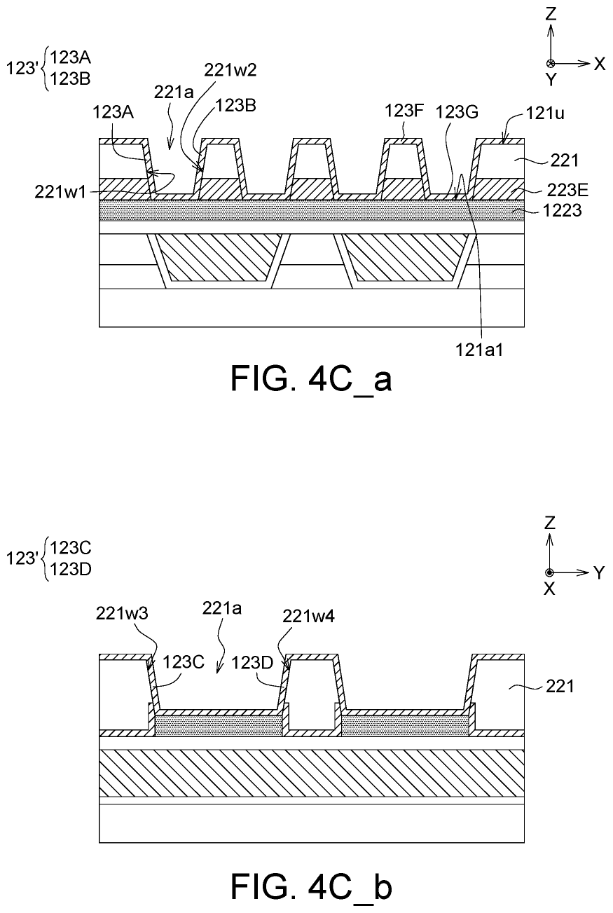

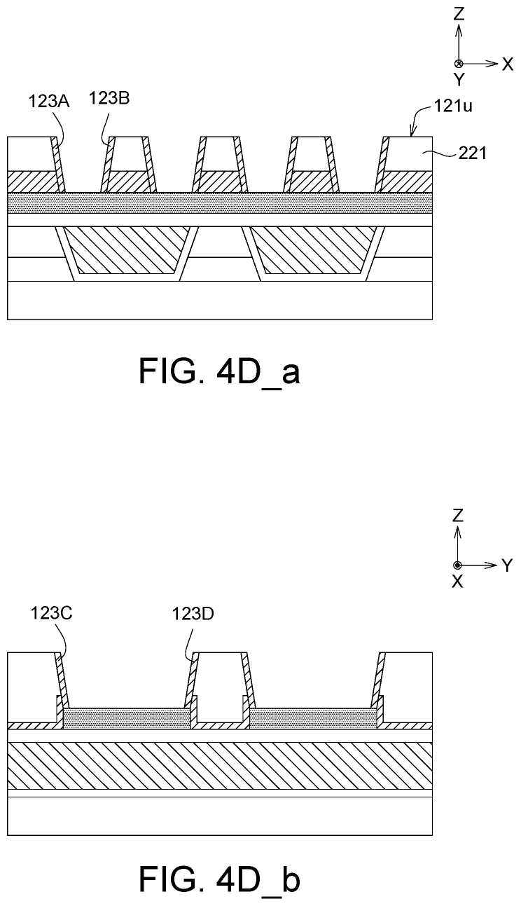

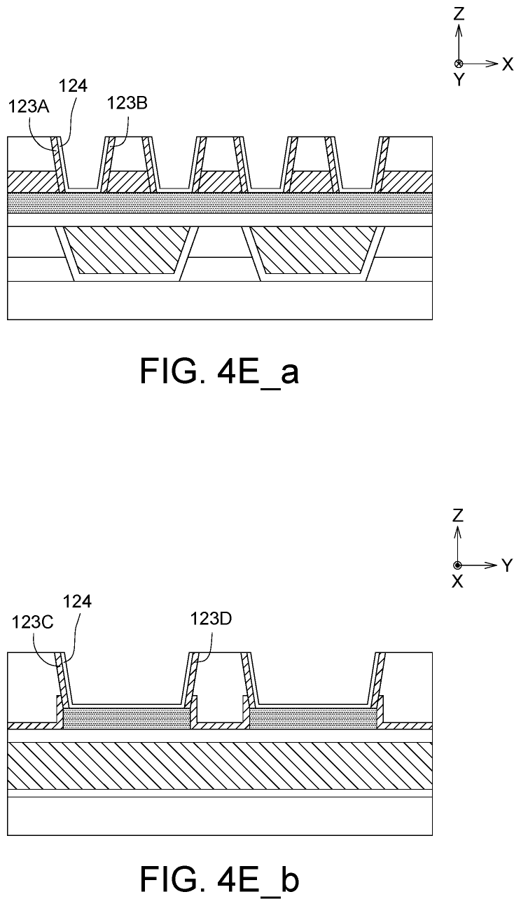

Referring to FIGS. 4A_a to 4E_b, FIGS. 4A_a to 4E_b illustrate schematic diagrams of manufacturing processes of the semiconductor device 200 of FIGS. 2a and 2b.

As shown in FIGS. 4A_a and 4A_b, the barrier dielectric layer 221 within the BEOL structure 220 is formed, wherein the BEOL structure 220 is formed over the FEOL structure 110, and the barrier dielectric layer 221 has the upper surface 221u and the lower surface 221b. The BEOL structure 220 further includes the fifth barrier 223E, wherein the fifth barrier 223E is in contact with the active layer 1223 (as shown in FIG. 4A_a), and the fifth barrier 223E is contact with the gate dielectric layer 125 (as shown in FIG. 4A_b).

In FIGS. 4A_a and 4A_b, the BEOL structure 220 further includes the active layer 1223, at least one gate 1222, the gate dielectric layer 125, the dielectric layer 126, the etching stop layer 127 and the gate connection layer 129.

The gate 1222 is formed in the dielectric layer 126 and the etching stop layer 127. The active layer 1223 is formed between the gate 1222 and the electrode element 1221 and extends in a direction, for example, the axis X. The gate dielectric layer 125 is formed between the active layer 1223 and the gate 1222. The dielectric layer 126 is formed between the gate dielectric layer 125 and the etching stop layer 127. The gate connection layer 129 is formed within the dielectric layer 126 and the etching stop layer 127, and the gate connection layer 129 is formed between the gate 1222 and the dielectric layer 126.

The gate dielectric layer 125 may be formed of a material including but not limited to HfOx, AlOx, etc, the dielectric layer 126 is, for example, an ILD layer, and the etching stop layer 127 may be formed of a material including but not limited to AlOx, AlN, SiON, etc. The gate connection layer 129 may be formed of a material the same as or similar to that of the electrode connection layer 128. The gate 1222 may be formed of a conductive material including, for example, copper, tungsten, TIN, etc. The active layer 1223 may be formed of a material including, for example, IGZO, InO, ITO, etc.

As shown in FIGS. 4B_a and 4B_b, the barrier dielectric layer 221 and the fifth barrier 223E are patterned. Furthermore, at least one through hole 221a passing through the barrier dielectric layer 221 and the fifth barrier 223E is formed by using photolithography including exposure, development and/or etching. After the through hole 221a being formed, the active layer 1223 is exposed from the through hole 221a. The through hole 221a has a first inner wall 221w1, a second inner wall 221w2 opposite to the first inner wall 221w1, a third inner wall 221w3 and a fourth inner wall 221w4 opposite to the third inner wall 221w3.

As shown in FIGS. 4C_a and 4C_b, a barrier layer 123′ over the inner wall 221w1, the second inner wall 221w2, the third inner wall 221w3 and the fourth inner wall 221w4 of the through hole 221a and the upper surface 221u of the barrier dielectric layer 221 is formed by using, for example, deposition, etc. The barrier layer 123′ includes the first barrier 123A, the second barrier 123B, the third barrier 123C, the fourth barrier 123D, the upper portion 123F and the lower portion 123G, wherein the first barrier 123A covers the entirety of the first inner wall 221w1 of the through hole 221a, the second barrier 123B covers the entirety of the second inner wall 221w2 of the through hole 221a, the third barrier 123C covers the entirety of the third inner wall 221w3 of the through hole 221a, the fourth barrier 123D covers the entirety of the fourth inner wall 221w4 of the through hole 221a, the upper portion 123F covers the upper surface 221u of the barrier dielectric layer 221, and the lower portion 123G covers a bottom surface 121al of the through hole 121a which exposes the active layer 1223.

As shown in FIGS. 4D_a and 4D_b, the upper portion 123F and the lower portion 123G of FIGS. 4C_a and 4C_b are removed by using, for example, etching back, etc. After the upper portion 123F and the lower portion 123G are removed, the upper surface 221u and the active layer 1223 are exposed.

As shown in FIGS. 4E_a and 4E_b, the electrode spacer 124 over the first barrier 123A, the second barrier 123B, the third barrier 123C, the fourth barrier 123D and the active layer 1223 is formed by deposition, etc.

Then, at least one electrode connection layer 128 and at least one the electrode element 1221 filling the through hole 221a is formed by deposition, etc., and then electrode connection layer 128 and the electrode element 1221 may be planarized by using a CMP to form the semiconductor device 200 as shown in FIGS. 2a and 2b. The electrode connection layer 128 is formed between the electrode element 1221 and the electrode spacer 124.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

According to the present disclosure, a semiconductor device includes a FEOL structure and a BEOL structure formed over the FEOL structure, wherein the BEOL structure includes at least one transistor and a barrier covering the entirety of a lateral surface of the electrode element. Accordingly, the sensitivity of the transistor may be maintained or even promoted, and the reliability is improved.

Example embodiment 1: a semiconductor device includes a FEOL structure and a BEOL structure. The BEOL structure is formed over the FEOL structure and includes a barrier dielectric layer, a transistor and a first barrier. The barrier dielectric layer has an upper surface and a lower surface. The transistor is partially formed in the barrier dielectric layer and includes an electrode element, and the electrode element has a first lateral surface, wherein the first lateral surface extends from the upper surface toward the lower surface. The first barrier covers the entirety of the first lateral surface of the electrode element.

Example embodiment 2 based on Example embodiment 1: the electrode element further has a second lateral surface opposite to the first lateral surface, and the second lateral surface extends from the upper surface toward the lower surface. The BEOL structure further includes a second barrier covering the entirety of the second lateral surface of the electrode element.

Example embodiment 3 based on Example embodiment 2: the electrode element further has a third lateral surface and a fourth surface opposite to the third lateral surface, the third lateral surface extends from the upper surface toward the lower surface, and the fourth lateral surface extends from the upper surface toward the lower surface. The BEOL structure further includes a third barrier and a fourth barrier, wherein the third barrier covers the entirety of the third lateral surface of the electrode element, and the fourth barrier covers the entirety of the fourth lateral surface of the electrode element.

Example embodiment 4 based on Example embodiment 1: the transistor further includes a gate and an active layer. The active layer is formed between the gate and the electrode element and extending in a direction. The BEOL structure further includes a fifth barrier extending in the direction, and the fifth barrier is connected to the first barrier.

Example embodiment 5 based on Example embodiment 4: the barrier dielectric layer includes an upper portion and a lower portion. The fifth barrier separates the upper portion from the lower portion.

Example embodiment 6 based on Example embodiment 2: the first barrier and the second barrier separate the electrode element from the barrier dielectric layer.

Example embodiment 7 based on Example embodiment 4: the BEOL structure further includes a gate dielectric layer. The gate dielectric layer is formed between the gate and the fifth barrier, and the fifth barrier is in contact with the gate dielectric layer.

Example embodiment 8 based on Example embodiment 1: the first barrier is formed of a material including AlOₓ, HfOₓ, SiNₓ, TiOₓ, SiCN, NiO, Fe₂O₃, Co₃O₄, MoO₂, Mn₃O₄, CuO, Sb₂O₃, SnO, Cr₂O₃, rare earth oxide, Ca—/Sr—/Bi-related Perovskite material or a combination thereof.

Example embodiment 9: a semiconductor device includes a FEOL structure and a BEOL structure. The BEOL structure is formed over the FEOL structure and includes a barrier dielectric layer, a transistor and a barrier layer. The transistor is partially formed within the barrier dielectric layer and includes an electrode element. The barrier layer isolates the barrier dielectric layer from the electrode element.

Example embodiment 10 based on Example embodiment 9: the electrode element further has a first lateral surface and a second lateral surface opposite to the first lateral surface; the barrier layer includes a first barrier and a second barrier opposite to the first barrier, the first barrier covers the entirety of the first lateral surface, and the second barrier covers the entirety of the second lateral surface.

Example embodiment 11 based on Example embodiment 10: the electrode element further has a third lateral surface and a fourth lateral surface opposite to the third lateral surface; the barrier layer includes a third barrier and a fourth barrier opposite to the third barrier, the third barrier covers the entirety of the third lateral surface, and the fourth barrier covers the entirety of the fourth lateral surface.

Example embodiment 12 based on Example embodiment 9: the transistor further includes a gate and an active layer. The active layer is formed between the gate and the electrode element and extending in a direction. The barrier layer includes a barrier extending in the direction.

Example embodiment 13 based on Example embodiment 12: the barrier dielectric layer includes an upper portion and a lower portion. The barrier separates the upper portion from the lower portion.

Example embodiment 14 based on Example embodiment 13: the barrier separates the electrode element from the upper portion and the lower portion.

Example embodiment 15 based on Example embodiment 12: the BEOL structure further includes a gate dielectric layer formed between the gate and the barrier, and the barrier is in contact with the gate dielectric layer.

Example embodiment 16: a manufacturing method for a semiconductor device includes the following steps: forming a barrier dielectric layer within a BEOL structure formed over a FEOL structure, wherein the barrier dielectric layer has an upper surface and a lower surface; forming a through hole passing through the barrier dielectric layer; forming a first barrier to cover a first inner wall of the through hole; and forming an electrode element within the through hole, wherein the electrode element has a first lateral surface extending from the upper surface toward the lower surface, and the first barrier covers the entirety of the first lateral surface of the electrode element.

Example embodiment 17 based on Example embodiment 16: the manufacturing method further includes: forming a second barrier to cover a second inner wall of the through hole, wherein in forming the electrode element within the through hole, the electrode element further has a second lateral surface opposite to the first lateral surface, and the second lateral surface extends from the upper surface toward the lower surface, the second barrier covers the entirety of the second lateral surface of the electrode element.

Example embodiment 18 based on Example embodiment 16: the manufacturing method further includes: forming a third barrier to cover a third inner wall of the through hole; and forming a fourth barrier to cover a fourth inner wall of the through hole; wherein in forming the electrode element within the through hole, the electrode element further has a third lateral surface and a fourth opposite to the third lateral surface, the third lateral surface extends from the upper surface toward the lower surface, the fourth lateral surface extends from the upper surface toward the lower surface, the third barrier covers the entirety of the third lateral surface of the electrode element, and the fourth barrier covers the entirety of the fourth lateral surface of the electrode element.

Example embodiment 19 based on Example embodiment 16: in forming the barrier dielectric layer within the BEOL structure, the BEOL structure includes a gate, a fifth barrier and an active layer formed between the barrier dielectric layer and the gate, and the active layer and the fifth barrier extend in a direction; in forming the first barrier to cover the first inner wall of the through hole, the fifth barrier is connected to the first barrier.

Example embodiment 20 based on Example embodiment 16: in forming the barrier dielectric layer within the BEOL structure, the BEOL structure includes a gate, a fifth barrier and an active layer formed between the barrier dielectric layer and the gate, and the fifth barrier is in contact with the active layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a FEOL (Front End of Line) structure;
a BEOL (Back End of Line) structure formed over the FEOL structure, comprising:
a barrier dielectric layer having an upper surface and a lower surface; and
a transistor partially formed in the barrier dielectric layer, comprising:
an electrode element having a first lateral surface, wherein the first lateral surface extends from the upper surface toward the lower surface; and
a first barrier covering an entirety of the first lateral surface of the electrode element.

2. The semiconductor device as claimed in claim 1, wherein the electrode element further has a second lateral surface opposite to the first lateral surface, and the second lateral surface extends from the upper surface toward the lower surface; the BEOL structure further comprising:
a second barrier covering an entirety of the second lateral surface of the electrode element.

3. The semiconductor device as claimed in claim 2, wherein the electrode element further has a third lateral surface and a fourth surface opposite to the third lateral surface, the third lateral surface extends from the upper surface toward the lower surface, and the fourth lateral surface extends from the upper surface toward the lower surface; the BEOL structure further comprising:
a third barrier covering an entirety of the third lateral surface of the electrode element; and
a fourth barrier covering an entirety of the fourth lateral surface of the electrode element.

4. The semiconductor device as claimed in claim 1, wherein the transistor further comprises:
a gate; and
an active layer formed between the gate and the electrode element and extending in a direction;
wherein the BEOL structure further comprises a fifth barrier extending in the direction, and the fifth barrier is connected to the first barrier.

5. The semiconductor device as claimed in claim 4, wherein the barrier dielectric layer comprises:
an upper portion; and
a lower portion;
wherein the fifth barrier separates the upper portion from the lower portion.

6. The semiconductor device as claimed in claim 2, wherein the first barrier and the second barrier separate the electrode element from the barrier dielectric layer.

7. The semiconductor device as claimed in claim 4, wherein the BEOL structure further comprises a gate dielectric layer; and wherein the gate dielectric layer is formed between the gate and the fifth barrier, and the fifth barrier is in contact with the gate dielectric layer.

8. The semiconductor device as claimed in claim 1, wherein the first barrier is formed of a material comprising AlOₓ, HfOₓ, SiNₓ, TiOₓ, SiCN, NiO, Fe₂O₃, Co₃₀₄, MoO₂, Mn₃O₄, CuO, Sb₂O₃, SnO, Cr₂O₃, rare earth oxide, Ca—/Sr—/Bi-related Perovskite material or a combination thereof.

9. A semiconductor device, comprising:
a FEOL structure;
a BEOL structure formed over the FEOL structure, comprising:
a barrier dielectric layer; and
a transistor partially formed within the barrier dielectric layer, comprising an electrode element; and
a barrier layer isolating the barrier dielectric layer from the electrode element.

10. The semiconductor device as claimed in claim 9, wherein the electrode element further has a first lateral surface and a second lateral surface opposite to the first lateral surface; and wherein the barrier layer comprises a first barrier and a second barrier opposite to the first barrier, the first barrier covers an entirety of the first lateral surface, and the second barrier covers an entirety of the second lateral surface.

11. The semiconductor device as claimed in claim 10, wherein the electrode element further has a third lateral surface and a fourth lateral surface opposite to the third lateral surface; and wherein the barrier layer comprises a third barrier and a fourth barrier opposite to the third barrier, the third barrier covers an entirety of the third lateral surface, and the fourth barrier covers an entirety of the fourth lateral surface.

12. The semiconductor device as claimed in claim 9, wherein the transistor further comprises:
a gate; and
an active layer formed between the gate and the electrode element and extending in a direction;
wherein the barrier layer comprises a barrier extending in the direction.

13. The semiconductor device as claimed in claim 12, wherein the barrier dielectric layer comprises:
an upper portion; and
a lower portion;
wherein the barrier separates the upper portion from the lower portion.

14. The semiconductor device as claimed in claim 13, wherein the barrier separates the electrode element from the upper portion and the lower portion.

15. The semiconductor device as claimed in claim 12, wherein the BEOL structure further comprises a gate dielectric layer formed between the gate and the barrier, and the barrier is in contact with the gate dielectric layer.

16. A manufacturing method for a semiconductor device, comprising:
forming a barrier dielectric layer within a BEOL structure formed over a FEOL structure, wherein the barrier dielectric layer has an upper surface and a lower surface;
forming a through hole passing through the barrier dielectric layer;
forming a first barrier to cover a first inner wall of the through hole; and
forming an electrode element within the through hole, wherein the electrode element has a first lateral surface extending from the upper surface toward to the lower surface, and the first barrier covers an entirety of the first lateral surface of the electrode element.

17. The manufacturing method as claimed in claim 16, further comprising:
forming a second barrier to cover a second inner wall of the through hole;
wherein in forming the electrode element within the through hole, the electrode element further has a second lateral surface opposite to the first lateral surface, and the second lateral surface extends from the upper surface toward the lower surface, the second barrier covers an entirety of the second lateral surface of the electrode element.

18. The manufacturing method as claimed in claim 16, further comprising:
forming a third barrier to cover a third inner wall of the through hole; and
forming a fourth barrier to cover a fourth inner wall of the through hole;
wherein in forming the electrode element within the through hole, the electrode element further has a third lateral surface and a fourth opposite to the third lateral surface, the third lateral surface extends from the upper surface toward the lower surface, the fourth lateral surface extends from the upper surface toward the lower surface, the third barrier covers an entirety of the third lateral surface of the electrode element, and the fourth barrier covers an entirety of the fourth lateral surface of the electrode element.

19. The manufacturing method as claimed in claim 16, wherein in forming the barrier dielectric layer within the BEOL structure, the BEOL structure comprises a gate, a fifth barrier and an active layer formed between the barrier dielectric layer and the gate, and the active layer and the fifth barrier extend in a direction; and in forming the first barrier to cover the first inner wall of the through hole, the fifth barrier is connected to the first barrier.

20. The manufacturing method as claimed in claim 16, wherein in forming the barrier dielectric layer within the BEOL structure, the BEOL structure comprises a gate, a fifth barrier and an active layer formed between the barrier dielectric layer and the gate, and the fifth barrier is in contact with the active layer.
